(19) United States
(12) Patent Application Publication
(10) Pub. No.: US 2026/0173374 A1
(43) Pub. Date: Jun. 18, 2026

(54) THREE-DIMENSIONAL MEMORY DEVICES AND FABRICATING METHODS THEREOF

(71) Applicant: Yangtze Memory Technologies Co., Ltd., Wuhan (CN)

(72) Inventors: Shuangshuang Wu, Wuhan (CN); Yuhui Han, Wuhan (CN); Di Wang, Wuhan (CN)

(21) Appl. No.: 19/008,445

(22) Filed: Jan. 2, 2025

(30) Foreign Application Priority Data
Dec. 16, 2024 (CN) 202411855969.7

(51) Int. Cl. H10B 43/27; G11C 16/04; H10B 41/10; H10B 41/27; H10B 41/35; H10B 43/10; H10B 43/35

(52) U.S. Cl. CPC H10B 43/27; G11C 16/0483; H10B 41/10; H10B 41/27; H10B 41/35; H10B 43/10; H10B 43/35

(57) ABSTRACT

Memory devices and fabricating methods thereof are disclosed. In certain aspects, a disclosed memory device comprises a stack structure including conductive layers and dielectric layers alternatively stacked in a vertical direction; a row of first channel structures along a first lateral direction, each vertically extending in the stack structure; a top select gate cut structure extending vertically in an upper portion of the stack structure and laterally along the first lateral direction and in contact with the first channel structures; and a row of first contact structures each comprising: a lower first contact portion having a lower surface in contact with a corresponding first channel structure and a side surface in contact with the top select gate cut structure, and an upper first contact portion on the lower first contact portion and having a lower surface and a side surface both in contact with the top select gate cut structure.

### CROSS-REFERENCE TO RELATED APPLICATIONS

This application claims the benefit of priority to Chinese Application No. 202411855969.7, filed on Dec. 16, 2024, which is hereby incorporated by reference in its entirety.

### TECHNICAL FIELD

The present disclosure generally relates to the field of semiconductor technology, and more particularly, to three-dimensional (3D) memory devices and fabricating methods thereof.

### BACKGROUND

With the continuous rise and development of artificial intelligence (AI), big data, Internet of Things (IoTs), mobile devices and communications, cloud storage, etc., the demand for memory capacity is growing in an exponential way. Compared with other non-volatile memories, NAND memory has many advantages, such as high integration, low power consumption, fast programming/erasing speed, good reliability, low cost, etc., and thus has gradually become the mainstream semiconductor memory in the industry.

Planar NAND memory cells are scaled to smaller sizes by improving process technology, circuit design, programming algorithm, and fabrication process. However, as feature sizes of the memory cells approach a lower limit, the planar process and fabrication techniques become challenging and costly. As a result, memory density for planar memory cells approaches an upper limit.

A three-dimensional (3D) NAND memory architecture can address the density limitation in planar memory cells. The 3D memory architecture includes a memory array and periphery devices for controlling signals to and from the memory array.

### SUMMARY

One aspect of the present disclosure provides a memory device, comprising: a stack structure including conductive layers and dielectric layers alternatively stacked in a vertical direction; a row of first channel structures along a first lateral direction, each vertically extending in the stack structure; a top select gate cut structure extending vertically in an upper portion of the stack structure and laterally along the first lateral direction and in contact with the first channel structures; and a row of first contact structures each comprising: a lower first contact portion having a lower surface in contact with a corresponding first channel structure and a side surface in contact with the top select gate cut structure, and an upper first contact portion on the lower first contact portion and having a lower surface and a side surface both in contact with the top select gate cut structure.

In some implementations, the upper first contact portions of the row of the channel structures laterally extend into the top select gate cut structure.

In some implementations, the first channel structure comprises: a memory layer on a sidewall of a channel hole vertically extending in the stack structure; a channel layer covering the memory layer; a filling structure surrounded by the channel layer; and a channel plug on the filling structure, in contact with the channel layer, and surrounded by the memory layer.

In some implementations, the channel plug has a first lateral dimension; the lower first contact portion is in contact with the channel plug and has a second lateral dimension greater than the first lateral dimension; and the upper first contact portion has a third lateral dimension greater than the second lateral dimension.

In some implementations, a lower sidewall of the top select gate cut structure is flat; and an upper sidewall of the top select gate cut structure has flat portions and curved portions alternately arranged along the first lateral direction.

In some implementations, the lower sidewall of the top select gate cut structure is in contact with the first channel structures and the side surfaces of the lower first contact portions of the first contact structures.

In some implementations, the curved portions of the upper sidewall of the top select gate cut structure are in contact with the side surfaces of the upper first contact portions of the first contact structures.

In some implementations, the memory layer comprises: a tunnelling layer in contact with the channel layer and the channel plug; a storage layer laterally surrounding the tunnelling layer; and a blocking layer laterally surrounding the storage layer; wherein the lower first contact portion is in contact with the tunnelling layer, the storage layer, and the blocking layer.

In some implementations, the memory device further comprises: a row of second channel structures having a distance from the top select gate cut structure; and a row of second contact structures each comprising: a lower second contact portion in contact with a corresponding channel plug of a corresponding second channel structure and having a fourth lateral dimension greater than the second lateral dimension, and an upper second contact portion on the lower second contact portion and having a fifth lateral dimension greater than the third lateral dimension.

In some implementations, a top surface of the top select gate cut structure is coplanar with a top surface of the upper first contact portion.

In some implementations, the memory device further comprises: a row of via structures each in contact with the upper first contact portion of a corresponding first contact structure.

Another aspect of the present disclosure provides a memory system, comprising: a memory device, comprising: a stack structure including conductive layers and dielectric layers alternatively stacked in a vertical direction; a row of first channel structures along a first lateral direction, each vertically extending in the stack structure; a top select gate cut structure extending vertically in an upper portion of the stack structure and laterally along the first lateral direction and in contact with the first channel structures; and a row of first contact structures each comprising: a lower first contact portion having a lower surface in contact with a corresponding first channel structure and a side surface in contact with the top select gate cut structure, and an upper first contact portion on the lower first contact portion and having a lower surface and a side surface both in contact with the top select gate cut structure; and a memory controller coupled with the memory device and configured to control the memory device.

Another aspect of the present disclosure provides a method of forming a memory device, comprising: forming a stack structure including conductive layers and dielectric layers alternatively stacked in a vertical direction; forming a row of first channel structures along a first lateral direction, each vertically extending in the stack structure; forming a top select gate cut structure extending vertically in an upper portion of the stack structure and laterally along the first lateral direction and in contact with the first channel structures; and forming a row of first contact structures, wherein forming each first contact structure comprises: forming a lower first contact portion having a lower surface in contact with a corresponding first channel structure and a side surface in contact with the top select gate cut structure, and forming an upper first contact portion on the lower first contact portion and having a lower surface and a side surface both in contact with the top select gate cut structure.

In some implementations, forming each first channel structure comprises: forming a channel hole vertically extending in the stack structure; forming a memory layer on a sidewall of the channel hole; forming a channel layer covering the memory layer; forming a filling structure surrounded by the channel layer; and forming a channel plug on the filling structure, in contact with the channel layer, and surrounded by the memory layer.

In some implementations, the channel plug is formed to have a first lateral dimension; the lower first contact portion is formed to be in contact with the channel plug and have a second lateral dimension greater than the first lateral dimension; and the upper first contact portion is formed to have a third lateral dimension greater than the second lateral dimension.

In some implementations, the method further comprises: after forming the channel plugs of the first channel structures, forming a sacrificial structure on each of the channel plugs; and forming an insulating layer covering the sacrificial structure; wherein forming the top select gate cut structure comprises removing portions of the insulating layer, the sacrificial structures, and the first channel structures.

In some implementations, forming the first contact structure comprises: removing upper portions of the sacrificial structures to form recesses; removing portions of the insulating layer and the top select gate cut structure to laterally expand the recesses to form upper recesses; and removing lower portions of the sacrificial structures to form lower recesses.

In some implementations, forming the first contact structure further comprises: depositing a conductive material into the lower recesses and the upper recesses; wherein the lower first contact portions are formed in the lower recesses, and the upper first contact portions are formed in the upper recesses.

In some implementations, forming the first contact structure further comprises: forming a lower sidewall of the top select gate cut structure being flat and in contact with the first channel structures and the side surfaces of the lower first contact portions of the first contact structures; and forming an upper sidewall of the top select gate cut structure including flat portions and curved portions alternately arranged along the first lateral direction, wherein the curved portions are in contact with the side surfaces of the upper first contact portions of the first contact structures.

In some implementations, forming the memory layer comprises: forming a blocking layer on the sidewall of the channel hole; forming a storage layer covering the blocking layer; and forming a tunnelling layer covering the storage layer; wherein the sacrificial structure is formed in contact with the tunnelling layer, the storage layer, and the blocking layer.

In some implementations, the method further comprises: forming a row of second channel structures having a distance from the top select gate cut structure; and forming a row of second contact structures each comprising: forming a lower second contact portion in contact with a corresponding channel plug of a corresponding second channel structure and having a fourth lateral dimension greater than the second lateral dimension, and forming an upper second contact portion on the lower second contact portion and having a fifth lateral dimension greater than the third lateral dimension.

In some implementations, the first channel structures and the second channel structures are formed simultaneously; and the first contact structures and the second contact structures are formed simultaneously.

In some implementations, the method further comprises: removing portions of the top select gate cut structure and portions of the upper first contact portions of the first contact structures, such that a top surface of the top select gate cut structure is coplanar with top surfaces of the upper first contact portions of the first contact structures.

In some implementations, the method further comprises: forming a row of via structures each in contact with the upper first contact portion of a corresponding first contact structure.

Other aspects of the present disclosure can be understood by those skilled in the art in light of the description, the claims, and the drawings of the present disclosure.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1 illustrates a schematic diagram of a cross-section of an exemplary 3D memory device, according to some aspects of the present disclosure.

FIG. 2 illustrates a schematic circuit diagram of an exemplary memory device, according to some aspects of the present disclosure.

FIG. 3 illustrates a schematic block diagram of an exemplary memory device, according to some aspects of the present disclosure.

FIG. 4 illustrates a schematic diagram of a portion of an exemplary 3D memory device in a planar view, according to some aspects of the present disclosure.

FIG. 5 illustrates a schematic diagram of a cross-section of a portion of an exemplary 3D memory device, according to some aspects of the present disclosure.

FIG. 6 illustrates a block diagram of an exemplary system having a 3D memory device, according to some aspects of the present disclosure.

FIG. 7A illustrates a diagram of an exemplary memory card having a 3D memory device, according to some aspects of the present disclosure.

FIG. 7B illustrates a diagram of an exemplary solid-state drive (SSD) having a 3D memory device, according to some aspects of the present disclosure.

FIG. 8 illustrates a flow diagram of an exemplary method for forming a 3D memory device, according to s some aspects of the present disclosure.

FIGS. 9A-9M illustrate schematic cross-sectional views of an exemplary 3D memory device at certain fabricating stages of the method shown in FIG. 8, according to some aspects of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present discloses.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnect access (via) contact structures are formed) and one or more dielectric layers.

As semiconductor technology advances, three-dimensional (3D) memory devices, such as 3D NAND memory devices, keep scaling more oxide/nitride (ON) layers of the memory cell array. With the increase of the number of array layers of the 3D architecture, the introduction of top select gate (TSG) cut in channel structures presents challenges. Specifically, the TSG cut can damage the upper portions of the channel structures. Further, as the increase of the number of array layers of the 3D architecture, the stress issues become worse, leading to a larger overlay shift between the upper channel structures and channel contacts, and reducing the landing area of via contacts on the channel contacts, which may cause high-resistance between contacts.

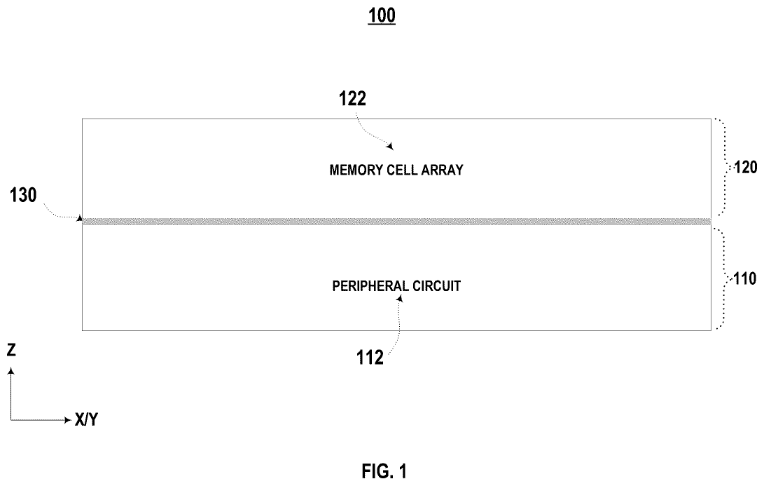

FIG. 1 illustrates a schematic view of a cross-section of a 3D memory device 100, according to some aspects of the present disclosure. 3D memory device 100 represents an example of a bonded chip. In some implementations, at least some of the components of 3D memory device 100 (e.g., first wafer/first semiconductor structure 110 and second wafer/second semiconductor structure 120 as shown in FIG. 1) are formed separately on different substrates in parallel and then jointed to form a bonded chip (a process referred to herein as a “parallel process”).

It is noted that X/Y and Z axes are added in FIG. 1 to further illustrate the spatial relationships of the components of a semiconductor device. A substrate of a semiconductor device, e.g., 3D memory device 100, includes two lateral surfaces (e.g., a top surface and a bottom surface) extending laterally in the x-direction (e.g., word line direction) and the y-direction (e.g., bit line direction). As used herein, whether one component (e.g., a layer or a device) is “on,” “above,” or “below” another component (e.g., a layer or a device) of a semiconductor device is determined relative to the substrate of the semiconductor device in the z-direction (the vertical direction or thickness direction) when the substrate is positioned in the lowest plane of the semiconductor device in the z-direction. The same notion for describing the spatial relationships is applied throughout the present disclosure.

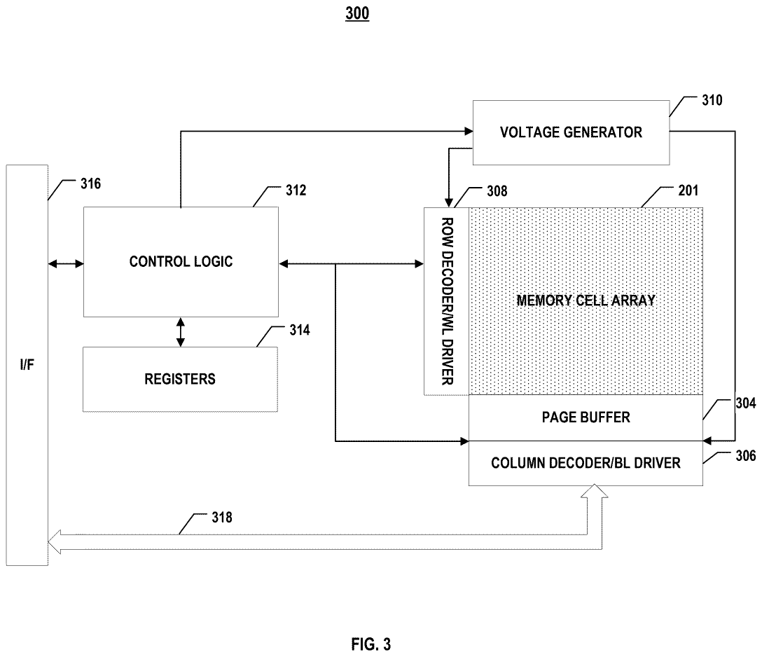

As shown in FIGS. 1, 3D memory device 100 can include a first semiconductor structure 110 including one or more periphery circuits 112 and a second semiconductor structure 120 including one or more memory cell arrays 122. That is, the memory cell arrays 122 and the periphery circuits 112 of the memory cell arrays 122 can be separated into at least two other semiconductor structures (e.g., 110 and 120 in FIG. 1).

In some implementations, the periphery circuits 112 can be coupled with the memory cell arrays 122 to perform read/program (write)/erase operations of the memory cell arrays 122. The periphery circuits 112 (a.k.a. control and sensing circuits) can include any suitable digital, analog, and/or mixed-signal circuits used for facilitating the operations of the memory cell arrays 122. For example, the periphery circuits 112 can include one or more of a page buffer, a decoder (e.g., a row decoder and a column decoder), a sense amplifier, a driver (e.g., a word line driver), an I/O circuit, a charge pump, a voltage source or generator, a current or voltage reference, any portions (e.g., a sub-circuit) of the functional circuits mentioned above, or any active or passive components of the circuit (e.g., transistors, diodes, resistors, or capacitors). The periphery circuits 112 in the first semiconductor structure 110 can use CMOS technology, e.g., which can be implemented with logic processes in any suitable technology nodes.

In some implementations, the second semiconductor structure 120 can include multiple memory cell arrays 122 that are separated by a spacer region (not shown). Each memory cell array 122 in the second semiconductor structure 120 can include an array of memory cells, such as an array of NAND Flash memory cells. For ease of description, a NAND Flash memory cell array may be used as an example for describing the memory cell array 122 in the present disclosure. But it is understood that the memory cell arrays 122 are not limited to NAND Flash memory cell arrays and may include any other suitable types of memory cell arrays, such as NOR Flash memory cell arrays, phase change memory (PCM) cell arrays, resistive memory cell arrays, magnetic memory cell arrays, spin transfer torque (STT) memory cell arrays, to name a few. In some implementations, the multiple memory cell arrays 122 can be the same type or be different types.

In some implementations, each memory cell array 122 can be a NAND Flash memory device in which memory cells are provided in the form of an array of 3D NAND memory strings, each of which extends vertically above the substrate (in 3D) through a stack structure, e.g., a memory stack. Depending on the 3D NAND technology (e.g., the number of layers/tiers in the memory stack), a 3D NAND memory string typically includes a certain number of NAND memory cells, each of which includes a floating-gate transistor or a charge-trap transistor. NAND memory cells can be organized into pages or fingers, which are then organized into blocks in which each NAND memory cell is coupled to a bit line (BL) and a word line (WL). In some implementations, a memory plane contains a certain number of blocks that are coupled through the same bit line. First semiconductor structure 110 can include one or more memory planes.

As shown in FIG. 1, the first semiconductor structure 110 and the second semiconductor structure 120 are stacked in the vertical direction (the z-direction). In some implementations, the first semiconductor structure 110 and the second semiconductor structure 120 are bonded together. Thus, the 3D memory device 100 further includes a bonding interface 130 vertically between the first semiconductor structure 110 and the second semiconductor structure 120. Bonding interface 130 can be an interface between two semiconductor structures formed by any suitable bonding technologies as described below in detail, such as hybrid bonding, anodic bonding, fusion bonding, transfer bonding, adhesive bonding, and eutectic bonding, to name a few.

The first semiconductor structure 110 and the second semiconductor structure 120 can be fabricated separately (and in parallel in some implementations) by the parallel process, such that the thermal budget of fabricating one of the first and second semiconductor structures 110 and 120 does not limit the processes of fabricating another one of the first and second semiconductor structures 110 and 120. Moreover, a large number of interconnects (e.g., bonding contact structures and/or inter-layer vias (ILVs)/through substrate vias (TSVs)) can be formed across the bonding interface 130 to make direct, short-distance (e.g., micron- or submicron-level) electrical connections between the first and second semiconductor structures 110 and 120, as opposed to the long-distance (e.g., millimeter or centimeter-level) chip-to-chip data bus on the circuit board, such as printed circuit board (PCB), thereby eliminating chip interface delay and achieving high-speed I/O throughput with reduced power consumption. Data transfer among the memory cell arrays 122 and the different periphery circuits 112 in the first and second semiconductor structures 110 and 120 can be performed through the interconnects (e.g., bonding contact structures and/or ILVs/TSVs) across bonding interface 130. By vertically integrating the first and second semiconductor structures 110 and 120, the chip size can be reduced, and the memory cell density can be increased.

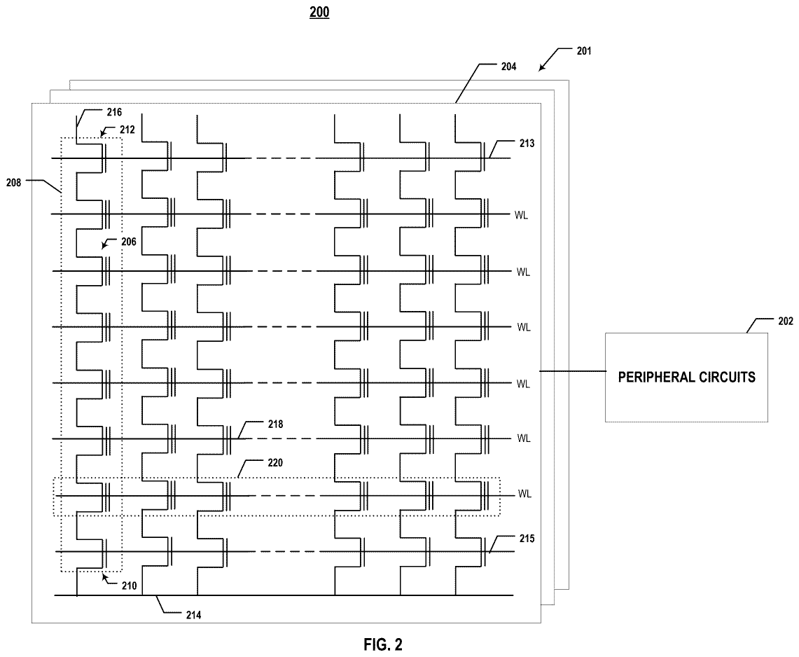

FIG. 2 illustrates a schematic circuit diagram of a memory device 200, according to some aspects of the present disclosure. Memory device 200 can include multiple memory cell arrays 201 and periphery circuits 202 coupled to the memory cell arrays 201. 3D memory device 100 may be an example of memory device 200 in which periphery circuits 202 may be included in the first and second semiconductor structures 110 and 120. Memory cell arrays 201 can be NAND Flash memory cell arrays in which memory cells 206 are provided in the form of arrays of NAND memory strings 208 each extending vertically above a substrate (not shown). In some implementations, each NAND memory string 208 includes a plurality of memory cells 206 coupled in series and stacked vertically. Each memory cell 206 can hold a continuous, analog value, such as an electrical voltage or charge, that depends on the number of electrons trapped within a region of memory cell 206. Each memory cell 206 can be either a floating gate type of memory cell including a floating-gate transistor or a charge trap type of memory cell including a charge-trap transistor.

In some implementations, each memory cell 206 is a single-level cell (SLC) that has two possible memory states and thus, can store one bit of data. For example, the first memory state “0” can correspond to a first range of voltages, and the second memory state “1” can correspond to a second range of voltages. In some implementations, each memory cell 206 is a multi-level cell (MLC) that is capable of storing more than a single bit of data in more than four memory states. For example, the MLC can store two bits per cell, three bits per cell (also known as triple-level cell (TLC)), or four bits per cell (also known as a quad-level cell (QLC)). Each MLC can be programmed to assume a range of possible nominal storage values. In one example, if each MLC stores two bits of data, then the MLC can be programmed to assume one of three possible programming levels from an erased state by writing one of three possible nominal storage values to the cell. A fourth nominal storage value can be used for the erased state.

As shown in FIG. 2, each NAND memory string 208 can include a source select gate (SSG) transistor 210 at its source end and a drain select gate (DSG) transistor 212 at its drain end. SSG transistor 210 and DSG transistor 212 can be configured to activate selected NAND memory strings 208 (columns of the array) during read and program operations. In some implementations, SSG transistors 210 of NAND memory strings 208 in the same block 204 are coupled through a same source line (SL) 214, e.g., a common SL, for example, to the ground. DSG transistor 212 of each NAND memory string 208 is coupled to a respective bit line 216 from which data can be read or programmed via an output bus (not shown), according to some implementations. In some implementations, each NAND memory string 208 is configured to be selected or deselected by applying a select voltage (e.g., above the threshold voltage of DSG transistor 212) or a deselect voltage (e.g., 0 V) to respective DSG transistor 212 through one or more DSG lines 213 and/or by applying a select voltage (e.g., above the threshold voltage of SSG transistor 210) or a deselect voltage (e.g., 0 V) to respective SSG transistor 210 through one or more SSG lines 215.

As shown in FIG. 2, NAND memory strings 208 can be organized into multiple blocks 204, each of which can have a common source line 214. In some implementations, each block 204 is the basic data unit for erase operations, i.e., all memory cells 206 on the same block 204 are erased at the same time. Memory cells 206 of adjacent NAND memory strings 208 can be coupled through word lines 218 that select which row of memory cells 206 is affected by read and program operations. In some implementations, each word line 218 is coupled to a page 220 of memory cells 206, which is the basic data unit for program and read operations. The size of one page 220 in bits can correspond to the number of NAND memory strings 208 coupled by word line 218 in one block 204. Each word line 218 can include a plurality of control gates (gate electrodes) at each memory cell 206 in respective page 220 and a gate line coupling the control gates. In some implementations, multiple blocks 204 can be organized into a memory plane (not shown), which forms one memory cell array 122 as shown in FIG. 1, and multiple memory planes can be formed on a same die, which constitutes the second semiconductor structure 120 as shown in FIG. 1.

Referring to FIG. 2, periphery circuits 202 can be coupled to memory cell arrays 201 through bit lines 216, word lines 218, source lines 214, SSG lines 215, and DSG lines 213. As described above, periphery circuits 202 can include any suitable circuits for facilitating the operations of memory cell arrays 201 by applying and sensing voltage signals and/or current signals through bit lines 216 to and from each target memory cell 206 through word lines 218, source lines 214, SSG lines 215, and DSG lines 213. Periphery circuits 202 can include various types of periphery circuits formed using CMOS technologies.

For example, FIG. 3 illustrates memory device 300 including a memory cell array 201 and various exemplary periphery circuits 202. Periphery circuits 202 include a page buffer 304, a column decoder/bit line driver 306, a row decoder/word line driver 308, a voltage generator 310, control logic 312, registers 314, an interface (I/F) 316, and a data bus 318. It is understood that in some examples, additional periphery circuits 202 may be included as well. It is noted that FIG. 3 shows only one memory cell array 201 for simplicity, but memory device 300 comprises multiple memory cell arrays 201 and corresponding periphery circuits 202 for each memory cell array 201.

Page buffer 304 can be configured to buffer data read from or programmed to memory cell array 201 according to the control signals of control logic 312. In one example, page buffer 304 may store one page of program data (write data) to be programmed into one page 220 of the memory cell array 201. In another example, page buffer 304 also performs program verify operations to ensure that the data has been properly programmed into memory cells 206 coupled to selected word lines 218.

Row decoder/word line driver 308 can be configured to be controlled by control logic 312 and select block 204 of the memory cell array 201 and a word line 218 of selected block 204. Row decoder/word line driver 308 can be further configured to drive the memory cell array 201. For example, row decoder/word line driver 308 may drive memory cells 206 coupled to the selected word line 218 using a word line voltage generated from voltage generator 310.

Column decoder/bit line driver 306 can be configured to be controlled by control logic 312 and select one or more 3D NAND memory strings 208 by applying bit line voltages generated from voltage generator 310. For example, column decoder/bit line driver 306 may apply column signals for selecting a set of N bits of data from page buffer 304 to be output in a read operation.

Control logic 312 can be coupled to each periphery circuit 202 and configured to control operations of periphery circuits 202. Registers 314 can be coupled to control logic 312 and include status registers, command registers, and address registers for storing status information, command operation codes (OP codes), and command addresses for controlling the operations of each periphery circuit 202.

Interface 316 can be coupled to control logic 312 and configured to interface the memory cell array 201 with a memory controller (not shown). In some implementations, interface 316 acts as a control buffer to buffer and relay control commands received from the memory controller and/or a host (not shown) to control logic 312 and status information received from control logic 312 to the memory controller and/or the host. Interface 316 can also be coupled to page buffer 304 and column decoder/bit line driver 306 via data bus 318 and act as an I/O interface and a data buffer to buffer and relay the program data received from the memory controller and/or the host to page buffer 304 and the read data from page buffer 304 to the memory controller and/or the host. In some implementations, interface 316 and data bus 318 are parts of an I/O circuit of periphery circuits 202.

Voltage generator 310 can be configured to be controlled by control logic 312 and generate the word line voltages (e.g., read voltage, program voltage, pass voltage, local voltage, and verification voltage) and the bit line voltages to be supplied to memory cell array 201. In some implementations, voltage generator 310 is part of a voltage source that provides voltages at various levels of different periphery circuits 202 as described below in detail. Consistent with the scope of the present disclosure, in some implementations, the voltages provided by voltage generator 310, for example, to row decoder/word line driver 308, column decoder/bit line driver 306, and page buffer 304 are above certain levels that are sufficient to perform the memory operations.

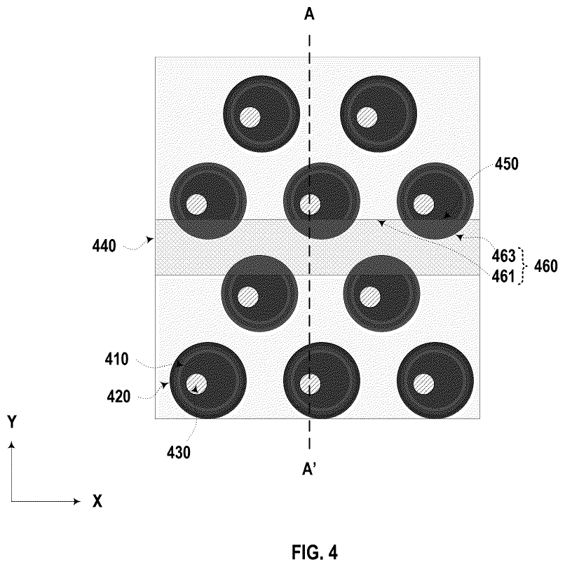

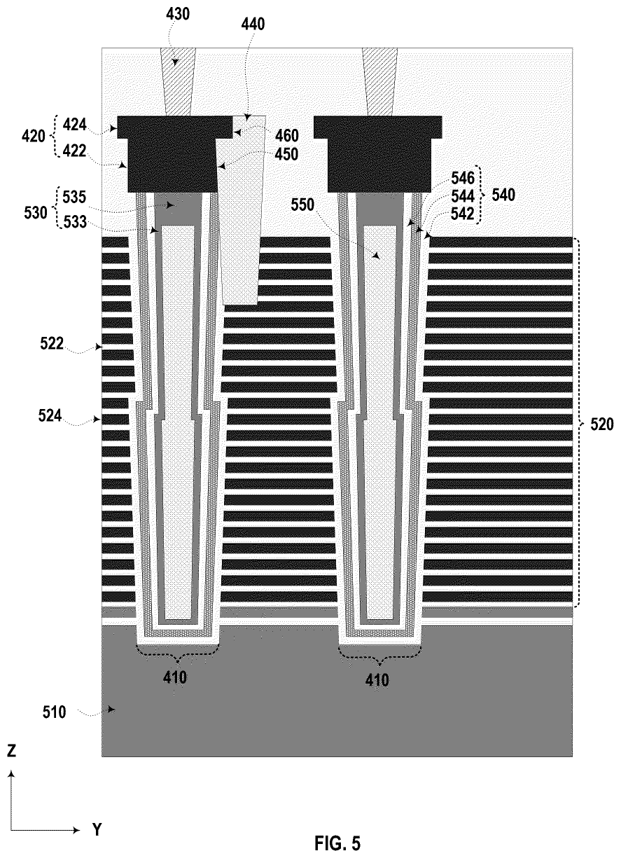

FIG. 4 illustrates a schematic diagram of a portion of an exemplary 3D memory device in a planar view, according to some aspects of the present disclosure. FIG. 5 illustrates a side view of a cross-section of the portion of the exemplary 3D memory device along the AA′ line shown in FIG. 4, according to some aspects of the present disclosure. It is noted that X, Y, and Z axes are included in FIGS. 4 and 5 to further illustrate the spatial relationship of the components in 3D memory device.

As shown in FIG. 4, in some implementations, in each memory cell array, the 3D NAND memory strings are formed based on an array of channel structures 410. In some implementations, each row of the channel structures 410 along the first lateral direction (i.e., the X-direction) can be aligned with each other. Adjacent rows of the channel structures 410 along the second lateral direction (i.e., the Y-direction) can be arranged in a staggered manner. In some implementations, a top select gate (TSG) cut structure 440 can laterally along the first lateral direction (i.e., the X-direction) between two adjacent rows of channel structures 410.

As shown in FIG. 5, a stack structure 520 including a plurality of dielectric layers 522 and conductive layers 524 alternatively stacked in a vertical direction can be located on a substrate 510. In some implementations, the substrate 510 can be a semiconductor substrate including silicon (e.g., single crystalline silicon, c-Si), silicon germanium (SiGe), gallium arsenide (GaAs), germanium (Ge), silicon-on-insulator (SOI), or any other suitable semiconductor materials.

In some implementations, a plurality of channel structures 410 can each vertically extend through the stack structure 520 into the substrate 510. As shown in FIG. 5, each channel structure 410 can have a cylinder shape (e.g., a pillar shape), can include a channel hole filled with a composite memory layer 540, a channel 530, and a filling structure 550 that are arranged radially from the center toward the outer surface of the pillar in this order, according to some implementations. The filling structure 550 can include dielectric materials, such as silicon oxide, and/or an air gap. The composite memory layer 540 can radially circumscribe the channel 530 along the lateral direction. The composite memory layer 540 can be formed laterally between the channel 530 and the stack structure 520. In some implementations, the composite memory layer 540 can include a block layer 542, a storage layer 544, and a tunneling layer 546. In some implementations, the channel 530 can include a channel layer 533 covering the tunneling layer 546, and a channel plug 535 on the filling structure 550, in contact with the channel layer 533, and surrounded by the memory layer 540. In some implementations, the channel 530 includes silicon, such as amorphous silicon, polysilicon, or single crystalline silicon. In some implementations, the channel 530 can include a doped portion and an undoped portion (not shown).

As shown in FIGS. 4 and 5, the TSG cut structure 440 can vertically extend in an upper portion of the stack structure 520, and laterally extend along the first lateral direction (i.e., the X-direction). In some implementations, the TSG cut structure 440 can include any suitable dielectric materials including, but not limited to, silicon oxide, silicon nitride, etc., or any combination thereof. In some implementations, the TSG cut structure 440 can partially cover lower portions of the two adjacent rows of channel structures 410. As shown in FIG. 5, in the lateral direction, the TSG cut structure 440 can be in contact with the two adjacent rows of channel structures 410. In some implementations, the TSG cut structure 440 can be in contact with curved side surfaces of the memory layer 540 and/or the channel layers 533 of the two adjacent rows of channel structures 410. That is, a lateral cross section of the memory layer 540 and/or the channel layers 533 of the channel structure 410 in an upper portion of the stack structure 520 can have a partial ring shape.

As shown in FIGS. 4 and 5, a channel contact structure 420 can be located on each channel structure 410. In some implementations, the channel contact structures 420 can include any suitable conductive materials including, but not limited to, W, Co, Cu, Al, silicides, or any combination thereof. In some implementations, a projection of the channel contact structure 420 on the substrate 510 can completely cover the projection of the channel structure 410 on the substrate 510. As shown in FIG. 5, each channel contact structure 420 can include a lower contact portion 422 and an upper contact portion 424. The lower contact portion 422 can have a lower surface in contact with a top surface of a corresponding channel structure 410. In some implementations, a top surface of the TSG cut structure 440 is coplanar with the top surfaces of the upper contact portions 424 of the channel contact structures 420.

As shown in FIGS. 4 and 5, the TSG cut structure 440 can be in contact with the two adjacent rows of channel contact structures 420. In some implementations, the TSG cut structure 440 can be in contact with a side surface of the lower contact portion 422, and in contact with both a lower surface and a side surface of the upper contact portion 424. That is, the upper contact portions 424 of the two adjacent rows of channel contact structures 420 can laterally extend into the TSG cut structure 440. The lower contact portion 422 can be in contact with one or more of the tunnelling layer 546, the storage layer 544, the blocking layer 542, the channel layer 533, and the channel plug 535.

As shown in FIGS. 4 and 5, in some implementations, a lower sidewall 450 of the TSG cut structure 440 is flat, and an upper sidewall 460 of the TSG cut structure 440 has flat portions 461 and curved portions 463 alternately arranged along the first lateral direction (i.e., the X-direction). The two lower sidewalls 450 of the TSG cut structure 440 are in contact with the two adjacent rows of channel structures 410 and the side surfaces of the lower contact portions 422 of two adjacent rows of the channel contact structures 420 on the two adjacent rows of channel structures 410. The curved portions 463 of the upper sidewall 460 of the TSG cut structure 440 are in contact with the side surfaces of the upper contact portions 424 of two adjacent rows of the channel contact structures 420 on the two adjacent rows of channel structures 410. That is, the lower contact portions 422 of two adjacent rows of the channel contact structures 420 in contact with the TSG cut structure 440 can have a flat sidewall in contact with the flat lower sidewall 450 of the TSG cut structure 440. The lower contact portions 422 of the rows of the channel contact structures 420 that have a distance from the TSG cut structure 440 do not have a flat sidewall.

In some implementations, the channel plug 535 of each channel structure 410 can have a first lateral dimension. The lower contact portions 422 of the two adjacent rows of channel contact structures 420 in contact with the TSG cut structure 440 can have a second lateral dimension greater than the first lateral dimension. The upper contact portions 424 of the two adjacent rows of channel contact structures 420 in contact with the TSG cut structure 440 can have a third lateral dimension greater than the second lateral dimension. The lower contact portions 422 of the rows of channel contact structures 420 that have a distance from the TSG cut structure 440 can have a fourth lateral dimension greater than the second lateral dimension. The upper contact portions 424 of the rows of channel contact structures 420 that have a distance from the TSG cut structure 440 can have a third lateral dimension greater than the third lateral dimension. In some implementations, the lower contact portions 422 of the rows of the channel contact structures 420 that have a distance from the TSG cut structure 440 can be aligned with the sidewall of the channel structure 410, i.e., the outer surface of the blocking layer 542.

In some implementations, in the disclosed 3D memory device, the channel contact structure 420 can include two portions. The lower contact portions 422 can be formed in the channel holes to reduce overlay shift between the channel structures 410 and the channel contact structures 420. The upper contact portions 424 of the channel contact structure 420 are formed after the formation of the TSG cut structure 440, which has a relatively large top surface of each channel contact structure 420. As such, when forming the via structures 430 each to be in contact with the top surface of the upper contact portion 424 of a corresponding channel contact structure 420, a relatively large landing area can be ensured, thereby reducing the misalignment risk, and reducing the resistance between the channel contact structure 420 and the via structures 430.

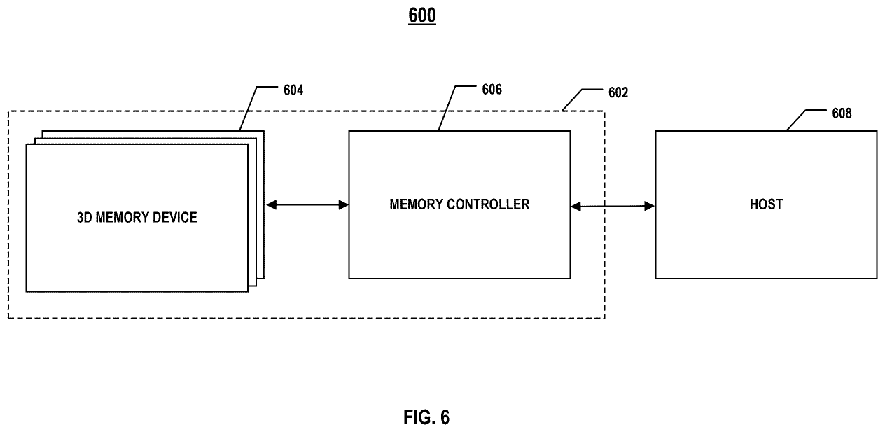

FIG. 6 illustrates a block diagram of an exemplary system 600 having a 3D memory device, according to some aspects of the present disclosure. System 600 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 6, system 600 can include a host 608 and a memory system 602 having one or more 3D memory devices 604 and a memory controller 606. Host 608 can be a processor of an electronic device, such as a central processing unit (CPU), or a system-on-chip (SoC), such as an application processor (AP). Host 608 can be configured to send or receive data to or from 3D memory devices 604.

3D memory device 604 can be any 3D memory devices disclosed herein, such as 3D memory device 100 shown in FIG. 1. In some implementations, each 3D memory device 604 includes a NAND Flash memory. Consistent with the scope of the present disclosure, the channel layer of 3D memory device 604 can be partially doped such that part of the channel layer that forms the source contact is highly doped to lower the potential barrier while leaving another part of the channel layer that forms the memory cells remaining undoped or lowly doped. One end of each channel structure of 3D memory device 604 can be opened from the backside to expose the doped part of the respective channel layer. 3D memory device 604 can further include a doped semiconductor layer electrically connecting the exposed doped parts of the channel layers to further reduce the contact resistance and sheet resistance. Moreover, 3D memory device 604 can include a composite dielectric film having a gate dielectric portion that faces the source select gate line(s). The gate dielectric portion can be free of silicon nitride (e.g., including only silicon oxide) and act as the gate dielectric of the SSG transistor. As a result, the electric performance of 3D memory device 604 can be improved, which in turn improves the performance of memory system 602 and system 600, e.g., achieving higher operation speed.

Memory controller 606 (a.k.a., a controller circuit) is coupled to 3D memory device 604 and host 608 and is configured to control 3D memory device 604, according to some implementations. Memory controller 606 can manage the data stored in 3D memory device 604 and communicate with host 608. In some implementations, memory controller 606 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 606 is designed for operating in a high duty-cycle environment SSDs or embedded multi-media-cards (eMMCs) used as data storage for mobile devices, such as smartphones, tablets, laptop computers, etc., and enterprise storage arrays. Memory controller 606 can be configured to control operations of 3D memory device 604, such as read, erase, and program operations. Memory controller 606 can also be configured to manage various functions with respect to the data stored or to be stored in 3D memory device 604 including, but not limited to bad-block management, garbage collection, logical-to-physical address conversion, wear leveling, etc. In some implementations, memory controller 606 is further configured to process error correction codes (ECCs) with respect to the data read from or written to 3D memory device 604. Any other suitable functions may be performed by memory controller 606 as well, for example, formatting 3D memory device 604. Memory controller 606 can communicate with an external device (e.g., host 608) according to a particular communication protocol. For example, memory controller 606 may communicate with the external device through at least one of various interface protocols, such as a USB protocol, an MMC protocol, a periphery component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

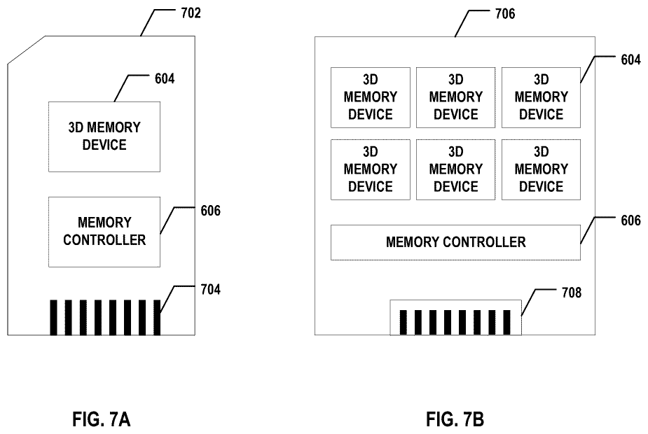

Memory controller 606 and one or more 3D memory devices 604 can be integrated into various types of storage devices, for example, be included in the same package, such as a universal Flash storage (UFS) package or an eMMC package. That is, memory system 602 can be implemented and packaged into different types of end electronic products. In one example as shown in FIG. 7A, memory controller 606 and a single 3D memory device 604 may be integrated into a memory card 702. Memory card 702 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 702 can further include a memory card connector 704 electrically coupling memory card 702 with a host (e.g., host 608 in FIG. 7). In another example as shown in FIG. 7B, memory controller 606 and multiple 3D memory devices 604 may be integrated into an SSD 706. SSD 706 can further include an SSD connector 708 electrically coupling SSD 706 with a host (e.g., host 608 in FIG. 7). In some implementations, the storage capacity and/or the operation speed of SSD 706 is greater than those of memory card 702.

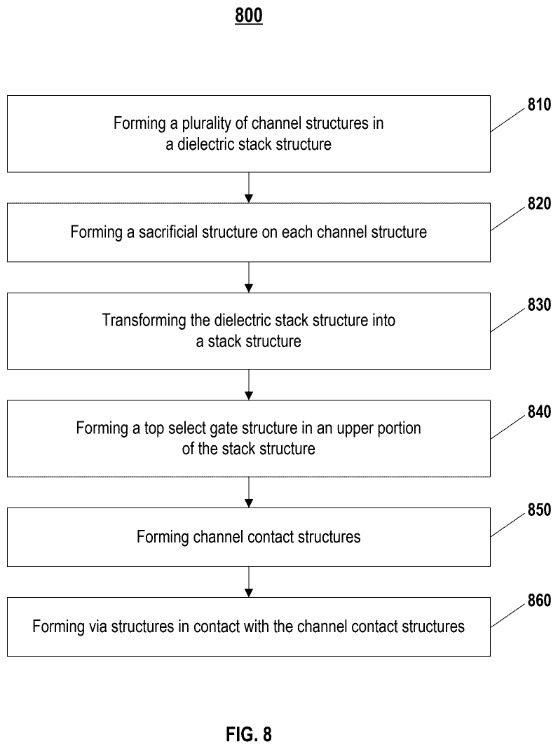

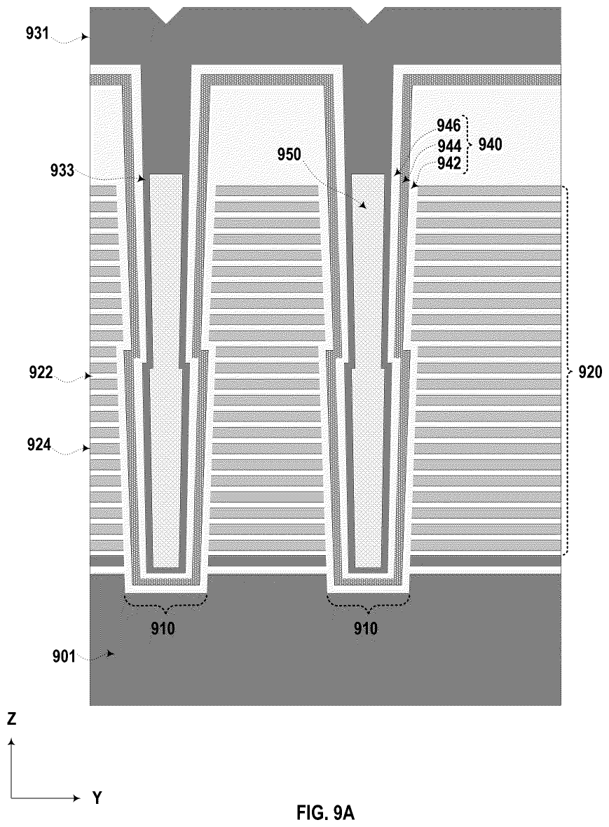

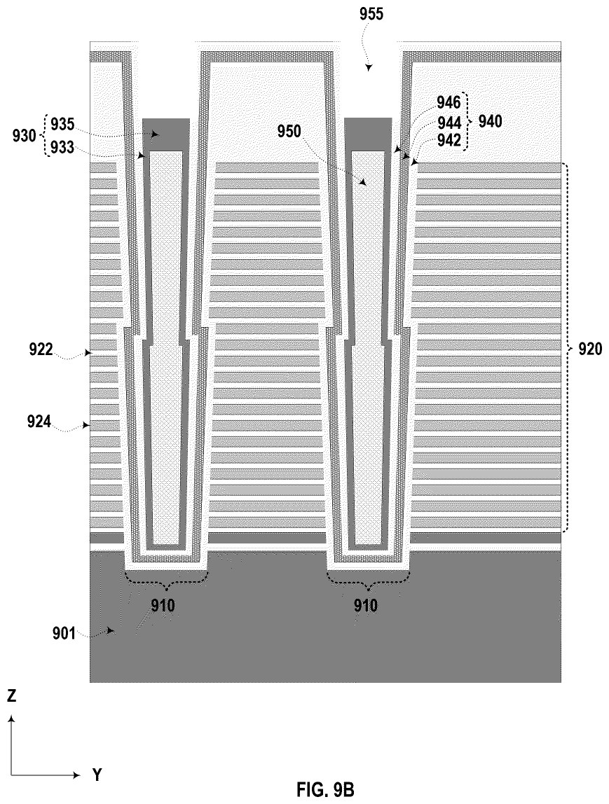

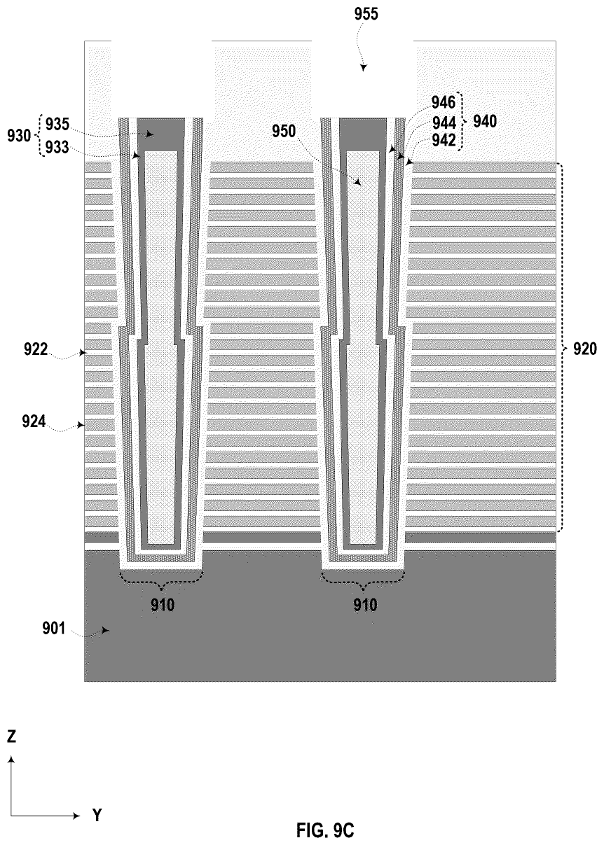

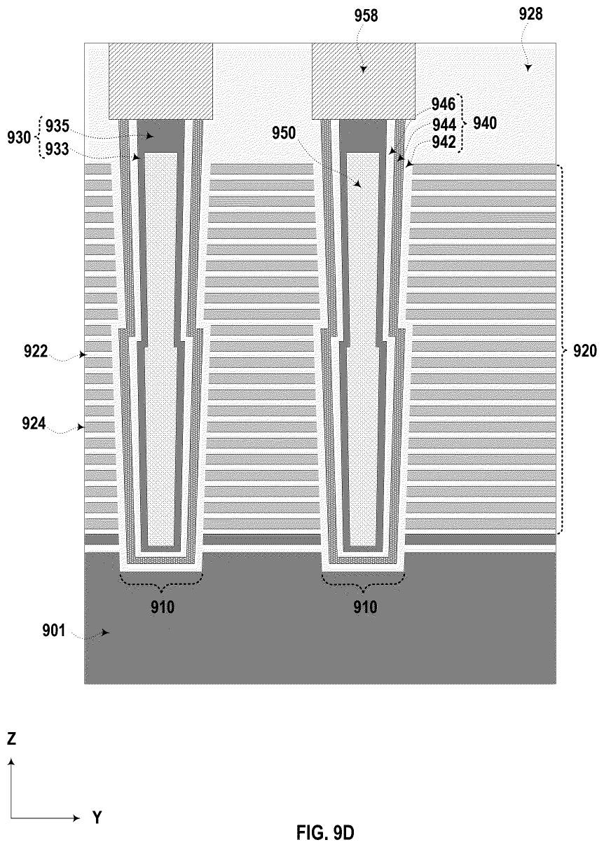

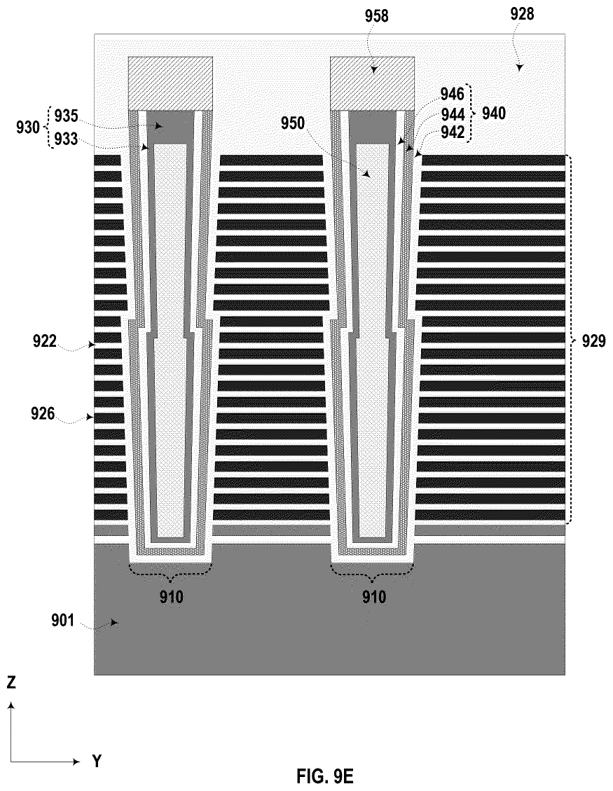

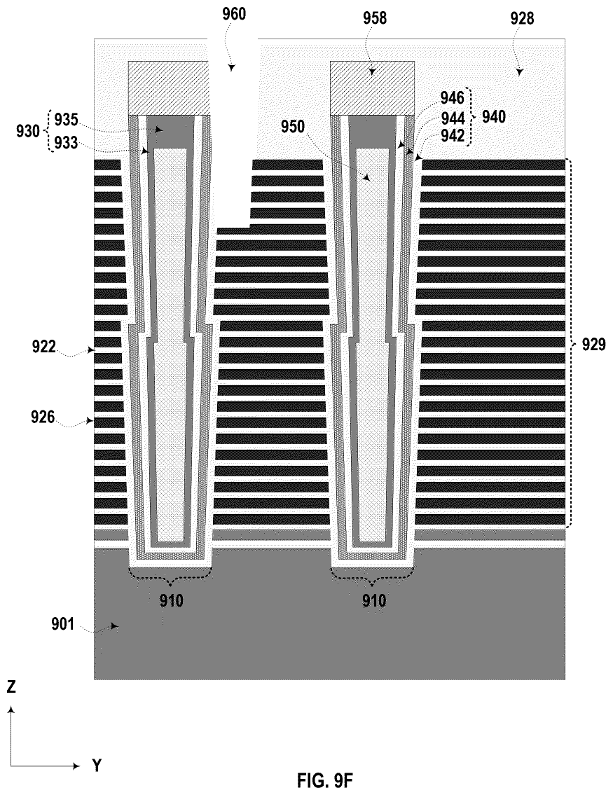

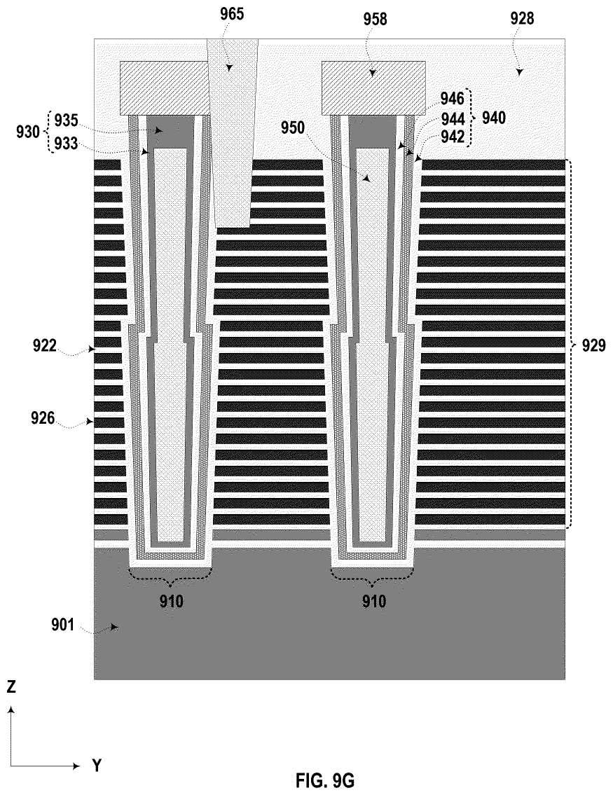

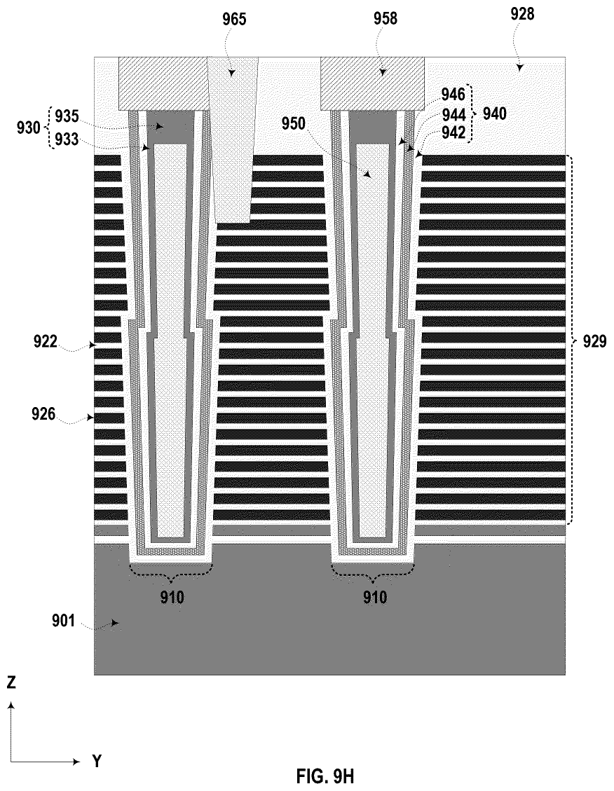

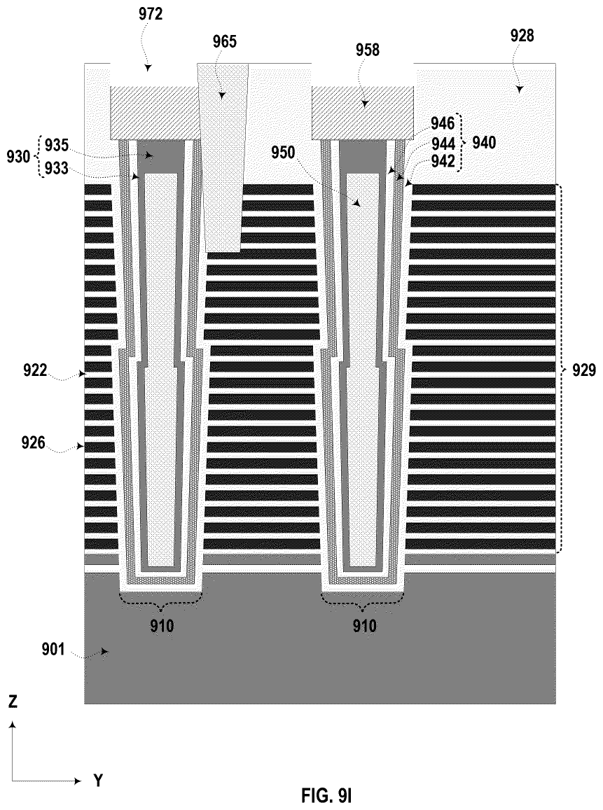

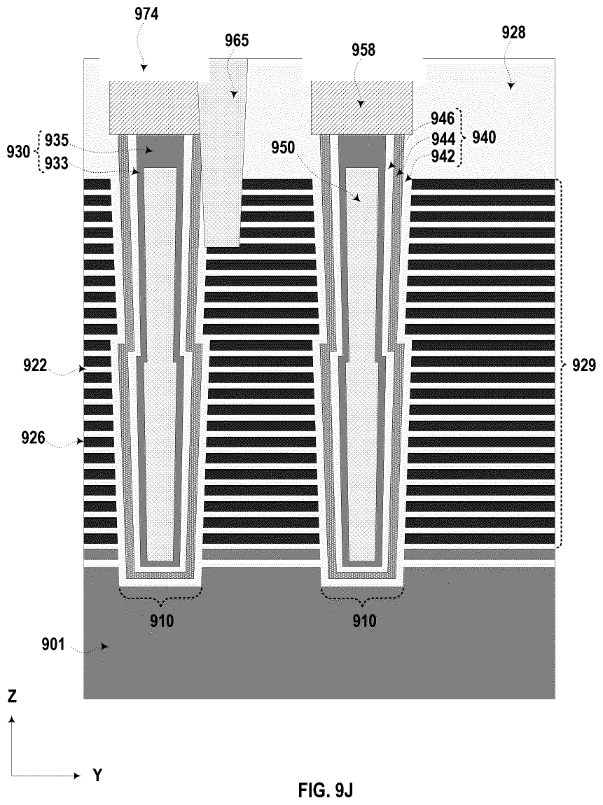

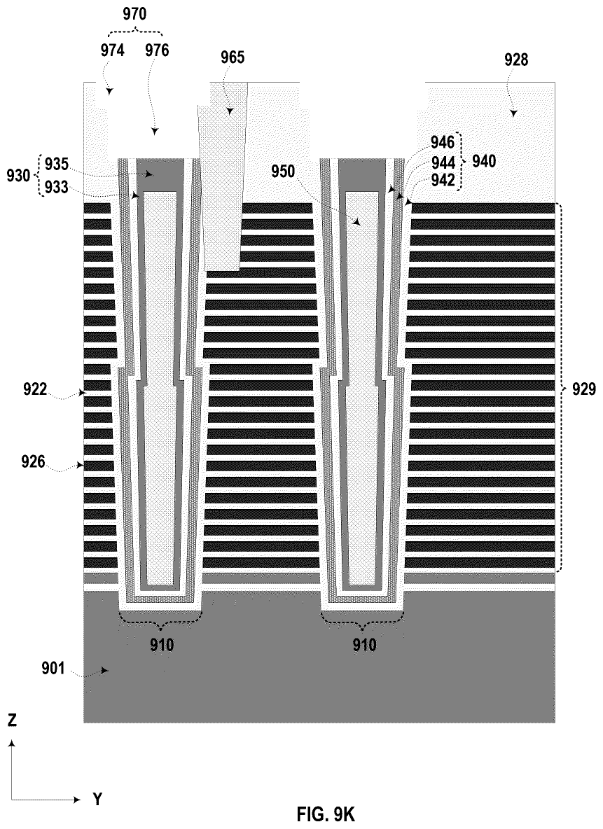

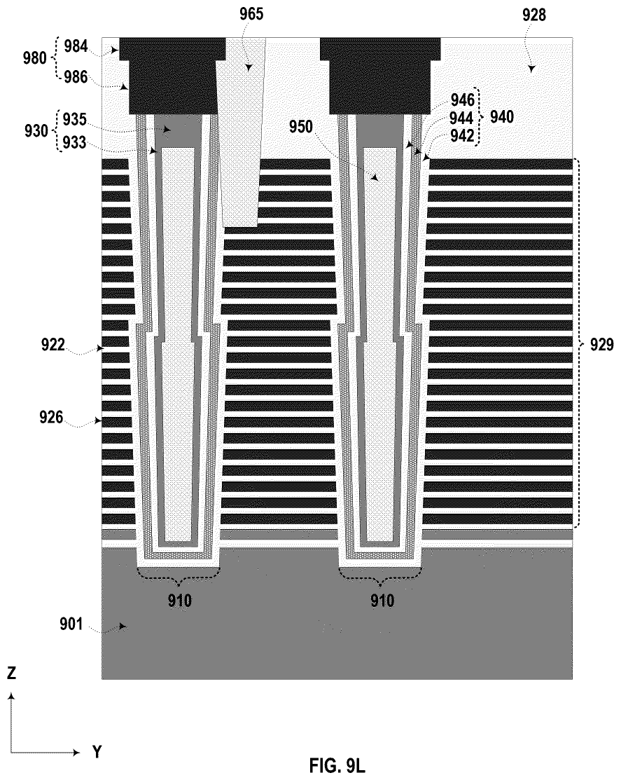

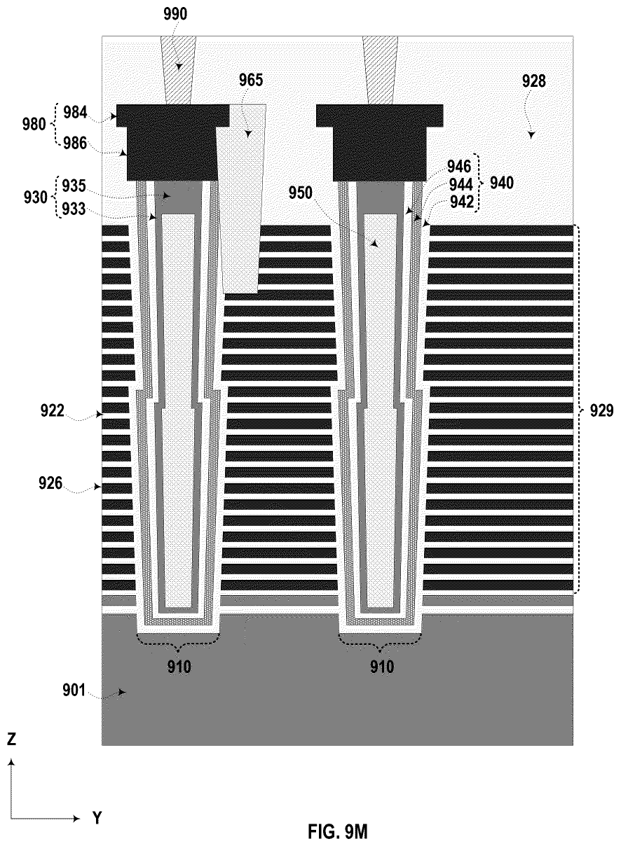

Referring to FIG. 8, a flow diagram of an exemplary method 800 for forming a 3D memory device is illustrated in accordance with some implementations of the present disclosure. It should be understood that, the operations shown in FIG. 8 are not exhaustive and that other operations can be performed as well before, after, or between any of the illustrated operations. Further, some of the operations may be performed simultaneously, or in a different order than shown in FIG. 8. FIGS. 9A-9M illustrate schematic cross-sectional views of an exemplary 3D memory device at certain fabricating stages of method 800 shown in FIG. 8 according to some implementations of the present disclosure.

As shown in FIG. 8, the method can start at operation 810, in which a dielectric stack structure can be formed on a substrate, and a plurality of channel structures can be formed in the dielectric stack structure. FIGS. 9A and 9B each illustrates a cross-sectional view of the 3D structure at a certain stage of the operation 810, according to some implementations of the present disclosure.

As shown in FIG. 9A, a dielectric stack structure 920 can be formed on a substrate 901. In some implementations, the substrate 901 can be any suitable semiconductor substrate having any suitable structure, such as a monocrystalline single-layer substrate, a polycrystalline silicon (polysilicon) single-layer substrate, a polysilicon and metal multi-layer substrate, etc.

The dielectric stack structure 920 can include an alternating stack of a first dielectric layer 922 (e.g., silicon oxide) and a second dielectric layer 924 (e.g., silicon nitride) that is different from first dielectric layer 922, for example. The plurality of first dielectric layers 922 and second dielectric layers 924 are extended in a lateral direction that is parallel to the surface of the substrate 901. In some implementations, there are more layers than the dielectric layer pairs made of different materials and with different thicknesses in the dielectric stack structure 920. The dielectric stack structure 920 can be formed by one or more thin film deposition processes including, but not limited to, Chemical Vapor Deposition (CVD), Physical Vapor Deposition (PVD), Atomic Layer Deposition (ALD), or any combination thereof.

In some implementations, the dielectric stack structure 920 can include a plurality of silicon oxide/nitride layer pairs. Each dielectric layer pair includes a layer of silicon oxide and a layer of silicon nitride. The plurality of oxide/nitride layer pairs are also referred to herein as an “alternating oxide/nitride stack.” That is, in the dielectric stack structure 920, multiple oxide layers 922 (shown in the areas with solid gray) and multiple nitride layers 924 (shown in the areas with meshes) alternate in a vertical direction. In other words, except a top and a bottom layer of a given alternating oxide/nitride stack, each of the other oxide layers 922 can be sandwiched by two adjacent nitride layers 924, and each of the nitride layers 924 can be sandwiched by two adjacent oxide layers 922.

The dielectric stack structure 920 can include any suitable number of layers of the oxide layers 922 and the nitride layers 924. In some implementations, the total number of layers of the oxide layers 922 and the nitride layers 924 in the dielectric stack structure 920 is equal to or larger than 64. That is, a number of oxide/nitride layer pairs can be equal to or larger than 32. In some implementations, the alternating oxide/nitride stack includes more oxide layers or more nitride layers with different materials and/or thicknesses than the oxide/nitride layer pair.

In some implementations, a plurality of channel structures 910 can be formed in the dielectric stack structure 920. Each channel structure 910 can vertically extend through the dielectric stack structure 920 into the substrate 901. In some implementations, the plurality of channel structures 910 can form an array form. In some implementations, the array of channel structures 910 can include a plurality of rows of channel structures 910. Each row of channel structures 910 can be aligned along the first lateral direction (i.e., the X-direction). Adjacent rows of channel structures 910 can be misaligned. In some implementations, the array of channel structures 910 can include a plurality of columns of channel structures 910. Each column of channel structures 910 can be aligned along the second lateral direction (i.e., the Y-direction). Adjacent columns of channel structures 910 can be misaligned.

In some implementations, the fabricating process for forming the multiple channel structures 910 can include forming multiple channel holes (not shown) penetrating the dielectric stack structure 920. A process of forming the multiple channel holes can include forming a hard mask layer (not shown) on the dielectric stack structure 920, and coating a photoresist layer (not shown) on the hard mask layer. A pattering process can be performed to pattern the hard mask layer. Using the hard mask layer as a mask, an etching process can be followed to etch the dielectric stack structure 920 to form the multiple channel holes. Each channel hole can completely penetrate the dielectric stack structure 920 and extend into the substrate 901. The etching process to form the multiple channel holes can be a dry etching, a wet etching, or a combination thereof. After the etching process, the photoresist layer and the hard mask layer can be removed.

In some implementations, a cleaning process can be performed to clean the multiple channel holes. The cleaning process can be a plasma ashing process including a high-temperature ashing, and/or a wet stripping. For example, a plasma source can be used to generate a reactive species, such as oxygen or fluorine. The reactive species can combine with the photoresist remaining in the channel holes to form ash, which can be removed with a vacuum pump. Specifically, in some implementations, monatomic oxygen plasma can be created by exposing oxygen gas at a low pressure to high-power radio waves, which ionize the oxygen gas. The residue of the reaction between the oxygen and photoresist material can generate ash in the plasma asher. The byproducts of the ashing process, such as volatile carbon oxides and water vapor, can be pumped away with the vacuum pump within the plasma asher.

A channel structure 910 can be formed in each channel hole in a subsequent process. The multiple channel structures 910 can be arranged in a staggered array form. In some implementations, each channel structure 910 can include an optional high-K dielectric layer (not shown), a memory layer 940 on the sidewall of the channel hole or covering the high-K dielectric layer, a channel layer 933 covering the memory layer 940, and a filling structure 950 enclosed by the channel layer 933. In some implementations, the memory layer 940 can include a barrier layer 942, a storage layer 944, and a tunneling layer 946.

In some implementations, fabrication processes to form the channel structures 910 can include forming an epitaxial layer (not shown) at a bottom of each channel hole. In some implementations, the epitaxial layer can be a polycrystalline silicon (polysilicon) layer formed by using a selective epitaxial growth (SEG) process. For example, an SEG pre-clean process can be performed to clean the multiple channel holes. A following deposition process can be performed to form a polysilicon layer at the bottom of each channel hole. In some implementations, any suitable doping process, such as an ion metal plasma (IMP) process, can be performed on the polysilicon layer to form the epitaxial layer. In some implementations, the epitaxial layer may not be directly formed on the surface of the substrate 901. One or more layers can be formed between the epitaxial layer and the substrate 901. That is, the epitaxial layer overlays the substrate 901.

In some implementations, fabrication processes to form the channel structures 410 can include forming a high-K dielectric layer (not shown) on the sidewall of each channel hole, and forming a memory layer 940 to cover the high-K dielectric layer. The memory layer 940 can be a composite dielectric layer, such as a combination of a barrier layer 942, a storage layer 944, and a tunneling layer 946. The high-K dielectric layer, the memory layer 940, including the barrier layer 942, the storage layer 944, and the tunneling layer 946, can be formed by one or more thin film deposition processes, such as ALD, CVD, PVD, any other suitable processes, or any combination thereof.

In some implementations, the barrier layer 942 and/or the high-K dielectric layer can be formed between the storage layer 944 and the sidewall of the channel hole. The barrier layer 942 and/or the high-K dielectric layer can be used for blocking the outflow of the electronic charges. In some implementations, the barrier layer 942 can be a silicon oxide layer or a combination of silicon oxide/silicon nitride/silicon oxide (ONO) layers. In some implementations, the high-K dielectric layer includes any suitable high dielectric constant (high k-value) dielectrics (e.g., aluminum oxide).

The storage layer 944 can be formed between the tunneling layer 946 and the barrier layer 942. Electrons or holes from the channel layer can tunnel to the storage layer 944 through the tunneling layer 946. The storage layer 944 can be used for storing electronic charges (electrons or holes) for memory operation. The storage or removal of charge in the storage layer 944 can impact the on/off state and/or conductance of the semiconductor channel. The storage layer 944 can include one or more films of materials including, but are not limited to, silicon nitride, silicon oxynitride, a combination of silicon oxide and silicon nitride, or any combination thereof. In some implementations, the storage layer 944 can include a nitride layer formed by using one or more deposition processes.

The tunneling layer 946 can be formed on the sidewall of the storage layer 944. The tunneling layer can be used for tunneling electronic charges (electrons or holes). The tunneling layer 946 can include dielectric materials including, but not limited to, silicon oxide, silicon nitride, silicon oxynitride, or any combination thereof. In some implementations, the tunneling layer 946 can be an oxide layer formed by using a deposition process.

In some implementations, fabrication processes to form the channel structures 910 further include forming a channel layer 933 covering the sidewall of the memory layer 940. In some implementations, channel layer 933 can be an amorphous silicon layer or a polysilicon layer formed by using a thin film deposition process, such as ALD, CVD, PVD, or any other suitable process.

In some implementations, fabrication processes to form the channel structures 910 further include forming a filling structure 950 to cover the channel layer 933 and fill the channel hole. In some implementations, the filling structure 950 can be an oxide layer formed by using any suitable deposition process, such as ALD, CVD, PVD, etc. In some implementations, the filling structure 950 can include one or more airgaps (not shown).

In some implementations, fabrication processes to form the channel structures 910 further include forming a channel plug 935 on the filling structure 950 in the upper portion of each channel hole, and in contact with the channel layer 933. In some implementations, the fabrication processes of the channel plugs 935 can include removing portions of the filling structure 950 to form a recess in the upper portion of each channel hole, and forming a channel plug layer 931 to fill the recesses and covering the channel layer 933, as shown in FIG. 9A. In some implementations, the channel plug layer 931 is an amorphous silicon layer or a polysilicon layer formed by using a thin film deposition process, such as ALD, CVD, PVD, or any other suitable process. In some implementations, the fabrication processes of the channel plugs 935 can further include removing portions of the channel plug layer 931 to form a recess 955 in the upper portion of each channel hole, as shown in FIG. 9B. The remaining portions of the channel plug layer 931 in the channel holes form the channel plugs 935, and the channel layer 933 and the channel plugs 935 in the channel holes form the channel 930.

Referring back to FIG. 8, the method proceeds to operation 820, in which a sacrificial structure can be formed on each channel structure. FIGS. 9C and 9D each illustrates a cross-sectional view of the 3D structure at a certain stage of the operation 820, according to some implementations of the present disclosure.

As shown in FIG. 9C, operation 820 can include removing potions of the memory layer 940 to enlarge the recesses 955. In some implementations, one or more etching processes can be performed to remove portions of the memory layer 940 outside the channel holes and exposed by the recesses 955. After the one or more etching processes, the upper surfaces of the channel plug 935 and the memory layer 940 can be approximately coplanar, as shown in FIG. 9C. The expanded recess 955 can have a lateral inner diameter approximately equal to the lateral outer diameter of the memory layer 940. As shown in FIG. 9D, a sacrificial structure 958 can be formed in each recess 955. In some implementations, the sacrificial structure 958 can include any suitable dielectric material different from the materials of the insulating layer 928 and the memory layer 940, and can be formed by using a thin film deposition process, such as ALD, CVD, PVD, or any other suitable process.

Referring back to FIG. 8, the method proceeds to operation 830, in which the dielectric stack structure can be transformed into a stack structure including multiple conductive/dielectric layer pairs. FIG. 9E illustrates a cross-sectional view of the 3D structure after the operation 830, according to some implementations of the present disclosure.

In some implementations, operation 830 can include forming a gate line slit (GLS, not shown) in the dielectric stack structure. In some implementations, the formed GLS can extend laterally in a straight line along the first lateral direction (i.e., the X-direction) between two arrays of channel structures 910, and vertically penetrate through the dielectric stack structure 920 into the substrate 901. The GLS can be formed by forming a mask layer over the dielectric stack structure 920 and patterning the mask using, e.g., photolithography, to form an opening corresponding to the GLS in the patterned mask layer. A suitable etching process, e.g., dry etch and/or wet etch, can be performed to remove portions of the dielectric stack structure 920 exposed by the opening until the GLS exposes the substrate 901. The mask layer can be removed after the formation of the GLS.

In some implementations, a gate replacement process (also known as the “word line replacement” process) can be performed to replace second dielectric layers 924 (e.g., silicon nitride) of the dielectric stack structure 920 with conductive layers 926. In some implementations, after forming the GLS, the second dielectric layers 924 in the dielectric stack structure 920 can be removed through the GLS to form multiple lateral trenches. The multiple lateral trenches can extend in a lateral direction, and can be used as spaces for conductive layers 926 to be formed in a subsequent process. The second dielectric layers 924 in the dielectric stack structure 920 are used as sacrificial layers, and are removed by using any suitable etching process, e.g., an isotropic dry etch or a wet etch. The etching process can have sufficiently high etching selectivity of the material of the second dielectric layers 924 over the materials of the first dielectric layer 922, such that the etching process can have minimal impact on the first dielectric layer 922. The isotropic dry etch and/or the wet etch and a following cleaning process can remove second dielectric layers 924 in various directions to expose the top and bottom surfaces of each first dielectric layer 922. As such, multiple lateral trenches can then be formed between first dielectric layers 922.

In some implementations, conductive layers 926 can be formed in the multiple lateral trenches. The multiple conductive layers 926 can be used as word lines (i.e., gate electrodes) in the 3D memory device. In some implementations, each conductive layers 926 can be coated with one or more insulating layers (not shown) used as gate dielectric layers for insulating the respective word line (i.e., gate electrode). In some implementations, one or more insulating layers (not shown) can be formed in each of the multiple lateral trenches to cover the exposed surfaces of the lateral trenches with one or more suitable insulating materials. For example, one or more suitable deposition processes, such as CVD, PVD, and/or ALD, can be utilized to deposit the one or more insulating materials into the lateral trenches. In some implementations, a recess etch and/or a chemical-mechanical planarization (CMP) can be used to remove excessive insulating material(s). The one or more insulating materials can include any suitable materials (e.g., high k-value dielectrics) that provide electric insulating function. For example, the one or more insulating materials can include silicon oxide, silicon nitride, silicon oxynitride, aluminum oxide, titanium nitride, etc., and/or any suitable combinations thereof. In some implementations, multiple insulating layers can have different insulating materials.

A conductive layer 926 can be formed in each lateral trench between the one or more insulating layers. The conductive layer 926 can be formed by filling the lateral trenches with a suitable gate electrode metal material. The conductive layer 926 can provide the base material for the subsequently-formed word lines (i.e., gate electrodes). The gate electrode metal material can include any suitable conductive material, e.g., tungsten, aluminum, copper, cobalt, or any combination thereof, for forming the word lines (i.e., gate electrodes). The gate electrode material can be deposited into lateral trenches using a suitable deposition method such as CVD, PVD, plasma-enhanced CVD (PECVD), sputtering, metal-organic chemical vapor deposition (MOCVD), and/or ALD. In some implementations, the conductive layers 926 include tungsten formed by CVD. As such, the dielectric stack structure 920 is transformed into a stack structure 929 including alternating conductive/dielectric layers.

Referring back to FIG. 8, the method proceeds to operation 840, in which a top select gate structure can be formed in an upper portion of the stack structure. FIGS. 9F, 9G, and 9H each illustrates a cross-sectional view of the 3D structure at a certain stage of the operation 840, according to some implementations of the present disclosure.

As shown in FIG. 9F, in some implementations, the operation 840 can include removing portions of the stack structure 929, the sacrificial structure 958, and the channel structures 910 in an upper portion of the stack structure to form a trench 960. In some implementations, the trench 960 can extend laterally along the first lateral direction (i.e., the X-direction) between adjacent rows of channel structures 910. The trench 960 can vertically extend in an upper portion of the stack structure 929 to expose upper portions of the memory layer 940, and/or the channel 930 of two adjacent rows of channel structures 910. The conductive layers 926 in the upper portion of the stack structure 929 can be divided by the trench 960.

In some other implementations, one or more suitable etching processes, e.g., dry etch and/or wet etch, can be performed to remove portions of the stack structure 929, portions of the sacrificial structure 958, and portions of the channel structures 910 to form the trench 960. A mask layer (not shown) can be used to control the shape of the trench 960 during the etching process. In some implementations, the channel 930 of the channel structure 910 is not removed during the etching process. As such, the lower portion of the trench 960 can have concave sidewalls. In some other implementations, portions of the channel 930 of the channel structure 910 can also be removed during the etching process. As such, the lower portion of the trench 960 can have substantial straight sidewalls. The mask layer can be removed after the formation of the trench 960.

As shown in FIG. 9G, a TSG cut structure 965 can be formed in the trench 960. In some implementations, a deposition process can then be performed to fill the trench 960 with any suitable filling material (e.g., silicon oxide) to form the TSG cut structure 965. In some implementations, the TSG cut structure 965 can be formed to partially cover lower portions of the two adjacent rows of channel structures 910. The TSG cut structure 965 can be in contact with the two adjacent rows of channel structures 910. In some implementations, the TSG cut structure 965 can be in contact with curved side surfaces of the memory layer 940 and/or the channel 930 of the two adjacent rows of channel structures 910. As shown in FIG. 9G, a CMP process can be performed, such that the top surface of the TSG cut structure 965 is coplanar with the top surfaces of the sacrificial structure 958.

Referring back to FIG. 8, the method proceeds to operation 850, in which channel contact structures can be formed. Each channel contact structure can include a lower contact portion and an upper contact portion. FIGS. 9I, 9J, 9K, and 9L each illustrates a cross-sectional view of the 3D structure at a certain stage of the operation 850, according to some implementations of the present disclosure.

As shown in FIG. 9I, upper portions of the sacrificial structures 958 can be removed to form a recess 972. In some implementations, any suitable etching process, e.g., a first selective wet etch, can be performed to remove upper portions of the sacrificial structures 958 to form the recesses 972. As shown in FIG. 9J, portions of the insulating layer 928 and the TSG cut structure 965 exposed by the recesses 972 can be removed to laterally expand the recesses 972 to form upper recesses 974. In some implementations, any suitable etching process, e.g., a second selective wet etch, can be performed to remove portions of the insulating layer 928 and the TSG cut structure 965 exposed by the recesses 972. As such, the recesses 972 can be laterally expended in to form upper recesses 974. As shown in FIG. 9K, the lower portions of the sacrificial structures 958 can be removed to form lower recesses 976. In some implementations, any suitable etching process, e.g., a third selective wet etch, can be performed to remove the lower portions of the sacrificial structures 958 to form the lower recesses 976. As shown in FIG. 9K, the lateral dimensions of the lower recesses 976 can be less than the lateral dimensions of the upper recesses 974. Each pair of interconnected lower recess 976 and upper recess 974 can constitute a channel contact opening 970.

As shown in FIG. 9L, a channel contact structure 980 can be formed in each channel contact opening 970. In some implementations, the channel contact structures 980 can be formed by depositing any suitable conductive materials including, but not limited to, W, Co, Cu, Al, silicides, or any combination thereof, by any suitable deposition method, such as CVD, PVD, ALD, etc. In some implementations, each channel contact structure 980 can include a lower contact portion 986 formed in the lower recess 976 and an upper contact portion 984 formed in the upper recess 974. The lower contact portion 986 can have a lower surface in contact with a top surface of the channel plug 935 of a corresponding channel structure 910. In some implementations, a top surface of the TSG cut structure 965 is coplanar with the top surfaces of the upper contact portions 984 of the channel contact structures 980. In some implementations, the TSG cut structure 965 can be in contact with the two adjacent rows of channel contact structures 980. In some implementations, the TSG cut structure 965 can be in contact with a side surface of the lower contact portion 986, and in contact with both a lower surface and a side surface of the upper contact portion 984, as shown in FIG. 9L.

Referring back to FIG. 8, the method proceeds to operation 860, in which a plurality of via structures can be formed. Each via structure can be in contact with the upper contact portion of a corresponding channel contact structure. FIG. 9M illustrates a cross-sectional view of the 3D structure after the operation 860, according to some implementations of the present disclosure.

As shown in FIG. 9M, a plurality of via structures 990 can be formed to be in contact with the corresponding channel contact structures 980. In some implementations, the plurality of via structures 990 can be formed by middle-end-of-line (MEOL) process or back-end-of-line (BEOL) process. In some implementations, a plurality of via structures 990 can be formed in an interlayer dielectric (ILD) layer (also known as “intermetal dielectric (IMD) layer”) including any suitable dielectric material, such as silicon oxide, silicon nitride, silicon oxynitride, low-k dielectrics, or any combination thereof. The plurality of via structures 990 can include any suitable conductive materials including, but not limited to, W, Co, Cu, Al, doped silicon, silicide, or any combination thereof, and formed by any suitable process, such as thin film deposition process, or patterning a conductive layer. Since each channel contact structure 980 has a large upper contact portion 984, providing a relatively large landing area for the via structure 990. Therefore, the misalignment risk between the via structures 990 and the channel contact structures 980 can be significantly reduced.

The foregoing description of the specific implementations will so fully reveal the general nature of the present disclosure that others can, by applying knowledge within the skill of the art, readily modify and/or adapt for various applications such specific implementations, without undue experimentation, without departing from the general concept of the present disclosure. Therefore, such adaptations and modifications are intended to be within the meaning and range of equivalents of the disclosed implementations, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

Implementations of the present disclosure have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The Summary and Abstract sections may set forth one or more but not all implementations of the present disclosure as contemplated by the inventor(s), and thus, are not intended to limit the present disclosure and the appended claims in any way.

The breadth and scope of the present disclosure should not be limited by any of the above-described implementations, but should be defined only in accordance with the following claims and their equivalents.

What is claimed is:

1. A memory device, comprising:
a stack structure including conductive layers and dielectric layers alternatively stacked in a vertical direction;
a row of first channel structures along a first lateral direction, each vertically extending in the stack structure;
a top select gate cut structure extending vertically in an upper portion of the stack structure and laterally along the first lateral direction and in contact with the first channel structures; and
a row of first contact structures each comprising:
a lower first contact portion having a lower surface in contact with a corresponding first channel structure and a side surface in contact with the top select gate cut structure, and
an upper first contact portion on the lower first contact portion and having a lower surface and a side surface both in contact with the top select gate cut structure.

2. The memory device of claim 1, wherein the first channel structure comprises:
a memory layer on a sidewall of a channel hole vertically extending in the stack structure;
a channel layer covering the memory layer;
a filling structure surrounded by the channel layer; and
a channel plug on the filling structure, in contact with the channel layer, and surrounded by the memory layer.

3. The memory device of claim 2, wherein:
the channel plug has a first lateral dimension;
the lower first contact portion is in contact with the channel plug and has a second lateral dimension greater than the first lateral dimension; and
the upper first contact portion has a third lateral dimension greater than the second lateral dimension.

4. The memory device of claim 1, wherein:
a lower sidewall of the top select gate cut structure is flat; and
an upper sidewall of the top select gate cut structure has flat portions and curved portions alternately arranged along the first lateral direction.

5. The memory device of claim 4, wherein:
the lower sidewall of the top select gate cut structure is in contact with the first channel structures and the side surfaces of the lower first contact portions of the first contact structures.

6. The memory device of claim 4, wherein:
the curved portions of the upper sidewall of the top select gate cut structure are in contact with the side surfaces of the upper first contact portions of the first contact structures.

7. The memory device of claim 2, wherein the memory layer comprises:
a tunnelling layer in contact with the channel layer and the channel plug;
a storage layer laterally surrounding the tunnelling layer; and
a blocking layer laterally surrounding the storage layer;
wherein the lower first contact portion is in contact with the tunnelling layer, the storage layer, and the blocking layer.

8. The memory device of claim 3, further comprising:
a row of second channel structures having a distance from the top select gate cut structure; and
a row of second contact structures each comprising:
a lower second contact portion in contact with a corresponding channel plug of a corresponding second channel structure and having a fourth lateral dimension greater than the second lateral dimension, and
an upper second contact portion on the lower second contact portion and having a fifth lateral dimension greater than the third lateral dimension.

9. The memory device of claim 1, further comprising:
a row of via structures each in contact with the upper first contact portion of a corresponding first contact structure;
wherein a top surface of the top select gate cut structure is coplanar with a top surface of the upper first contact portion 10. A memory system, comprising:
a memory device, comprising:
a stack structure including conductive layers and dielectric layers alternatively stacked in a vertical direction;
a row of first channel structures along a first lateral direction, each vertically extending in the stack structure;
a top select gate cut structure extending vertically in an upper portion of the stack structure and laterally along the first lateral direction and in contact with the first channel structures; and
a row of first contact structures each comprising:
a lower first contact portion having a lower surface in contact with a corresponding first channel structure and a side surface in contact with the top select gate cut structure, and
an upper first contact portion on the lower first contact portion and having a lower surface and a side surface both in contact with the top select gate cut structure; and
a memory controller coupled with the memory device and configured to control the memory device.

11. A method of forming a memory device, comprising:
forming a stack structure including conductive layers and dielectric layers alternatively stacked in a vertical direction;
forming a row of first channel structures along a first lateral direction, each vertically extending in the stack structure;
forming a top select gate cut structure extending vertically in an upper portion of the stack structure and laterally along the first lateral direction and in contact with the first channel structures; and
forming a row of first contact structures, wherein forming each first contact structure comprises:
forming a lower first contact portion having a lower surface in contact with a corresponding first channel structure and a side surface in contact with the top select gate cut structure, and
forming an upper first contact portion on the lower first contact portion and having lower surface and a side surface both in contact with the top select gate cut structure.

12. The method of claim 11, wherein forming each first channel structure comprises:
forming a channel hole vertically extending in the stack structure;
forming a memory layer on a sidewall of the channel hole;
forming a channel layer covering the memory layer;
forming a filling structure surrounded by the channel layer; and
forming a channel plug on the filling structure, in contact with the channel layer, and surrounded by the memory layer.

13. The method of claim 12, wherein:
the channel plug is formed to have a first lateral dimension;
the lower first contact portion is formed to be in contact with the channel plug and have a second lateral dimension greater than the first lateral dimension; and
the upper first contact portion is formed to have a third lateral dimension greater than the second lateral dimension.

14. The method of claim 12, further comprising:
after forming the channel plugs of the first channel structures, forming a sacrificial structure on each of the channel plugs; and
forming an insulating layer covering the sacrificial structure;
wherein forming the top select gate cut structure comprises removing portions of the insulating layer, the sacrificial structures, and the first channel structures.

15. The method of claim 14, wherein forming the first contact structure comprises:
removing upper portions of the sacrificial structures to form recesses;
removing portions of the insulating layer and the top select gate cut structure to laterally expand the recesses to form upper recesses; and
removing lower portions of the sacrificial structures to form lower recesses.

16. The method of claim 15, wherein forming the first contact structure further comprises:
depositing a conductive material into the lower recesses and the upper recesses;
wherein the lower first contact portions are formed in the lower recesses, and the upper first contact portions are formed in the upper recesses.

17. The method of claim 11, wherein forming the first contact structure further comprises:
forming a lower sidewall of the top select gate cut structure being flat and in contact with the first channel structures and the side surfaces of the lower first contact portions of the first contact structures; and
forming an upper sidewall of the top select gate cut structure including flat portions and curved portions alternately arranged along the first lateral direction, wherein the curved portions are in contact with the side surfaces of the upper first contact portions of the first contact structures.

18. The method of claim 14, wherein forming the memory layer comprises:
forming a blocking layer on the sidewall of the channel hole;
forming a storage layer covering the blocking layer; and
forming a tunnelling layer covering the storage layer;
wherein the sacrificial structure is formed in contact with the tunnelling layer, the storage layer, and the blocking layer.

19. The method of claim 13, further comprising:
forming a row of second channel structures having a distance from the top select gate cut structure; and
forming a row of second contact structures each comprising:
forming a lower second contact portion in contact with a corresponding channel plug of a corresponding second channel structure and having a fourth lateral dimension greater than the second lateral dimension, and
forming an upper second contact portion on the lower second contact portion and having a fifth lateral dimension greater than the third lateral dimension.

20. The method of claim 13, further comprising:
removing portions of the top select gate cut structure and portions of the upper first contact portions of the first contact structures, such that a top surface of the top select gate cut structure is coplanar with top surfaces of the upper first contact portions of the first contact structures; and
forming a row of via structures each in contact with the upper first contact portion of a corresponding first contact structure.
